(19) United States
(12) Patent Application Publication
(10) Pub. No.: US 2008/0116548 A1
(43) Pub. Date: May 22, 2008

(54) WIRE BOND AND METHOD OF FORMING SAME

(75) Inventors: Zhe Li, Tianjin (CN); Ying-Wei Jiang, Tianjin (CN); Guo-Ping Lu, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC, Austin, TX (US)

(21) Appl. No.: 11/863,259

(22) Filed: Sep. 28, 2007

(30) Foreign Application Priority Data
Nov. 17, 2006 (CN) 200610149236.7

(51) Int. Cl. H01L 23/495; B23K 31/02

(52) U.S. Cl. 257/676; 228/256; 257/E23.031

(57) ABSTRACT

In a semiconductor package having a plurality of wire bond interconnections between a semiconductor chip and a chip carrier, a wire bond (20) including a first stitch bond (22) formed at a first location (24) on a bonding site (26), and a second stitch bond (40) formed at a second location (42) on the bonding site (26) such that the second bond (40) forms two crescent shaped areas (48, 50) and overlaps the first bond (22).

### BACKGROUND OF THE INVENTION

The present invention relates to wirebonding and more particularly to a wire bond and a method of forming the wire bond.

Wirebonding is a widely used technique for providing electrical connection between a semiconductor chip and a chip carrier. Wirebonding typically involves forming a first wire bond on a bond pad of the semiconductor chip and a second wire bond on a lead finger of a lead frame or a pad surface of a substrate. Referring now to FIG. 14 an enlarged top plan view of a conventional second wire bond 10 including a wire 12 bonded to a lead finger 14 is shown. The second bond 10 includes a crescent-shaped bond area 16 formed by an imprint of an outer geometry of a capillary bonding tool (not shown) that is used to form the second bond 10.

Wire bond interconnections formed between the semiconductor chip and the chip carrier may be evaluated visually and/or by mechanical testing methods. A peel strength test is one such mechanical testing method. The peel strength of a wire bond provides an indication of the likelihood of bond failure. The peel strength test is performed by placing a hook under the wire proximate to a wire bond and applying a lifting force to test the strength of the adhesion of the wire bond to the bonding site. Typically, when a second wire bond is identified as having low peel strength, one or more bonding parameters of the second wire bond such as, for example, bonding force, bonding time, and ultrasonic frequency and power, are varied to increase the peel strength of the second bond. However, this often leads to a reduction in the thickness of the bond area of the second bond, making the second bond more susceptible to heel cracking. Heel cracking significantly reduces the pull strength of the second bond and is also known to cause premature cycling failures. Thus, a need exists for a wire bond with increased peel strength and bond area thickness, and a method of forming such a wire bond.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged top plan view of a conventional wire bond;

FIG. 2 is an enlarged cross-sectional view illustrating a step in the formation of a first bond at a first location on a bonding site in accordance with an embodiment of the present invention;

FIG. 3 is an enlarged cross-sectional view illustrating an upward movement of a bonding tool in accordance with an embodiment of the present invention;

FIG. 4 is an enlarged cross-sectional view illustrating a reverse movement of the bonding tool of FIG. 3;

FIG. 5 is an enlarged cross-sectional view illustrating the formation of a second bond at a second location on the bonding site of FIG. 2;

FIG. 6 is an enlarged cross-sectional view illustrating a step of breaking the wire after the formation of the second bond in accordance with an embodiment of the present invention;

FIG. 7 is an enlarged top plan view of a wire bond in accordance with an embodiment of the present invention; and

FIG. 8 is an enlarged side view of a wire bond in accordance with an embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides, in a semiconductor package having a plurality of wire bond interconnections between a semiconductor chip and a chip carrier, a wire bond including a first bond formed at a first location on a bonding site, and a second bond formed at a second location on the bonding site such that the second bond at least partially overlaps the first bond.

The present invention also provides a semiconductor packaged device including a lead frame having a plurality of lead fingers, and a chip attached to the lead frame. The chip includes a plurality of bond pads. Ones of the bond pads are electrically connected with respective ones of the lead fingers by a plurality of wires such that a bond connecting one of the wires to a corresponding lead finger is a forward-folded type stitch bond.

The present invention further provides a method of forming a wire bond including the steps of forming a first bond by bonding a first portion of a wire at a first location on a bonding site with a bonding tool, and forming a second bond by bonding a second portion of the wire at a second location on the bonding site with the bonding tool such that the second bond at least partially overlaps the first bond.

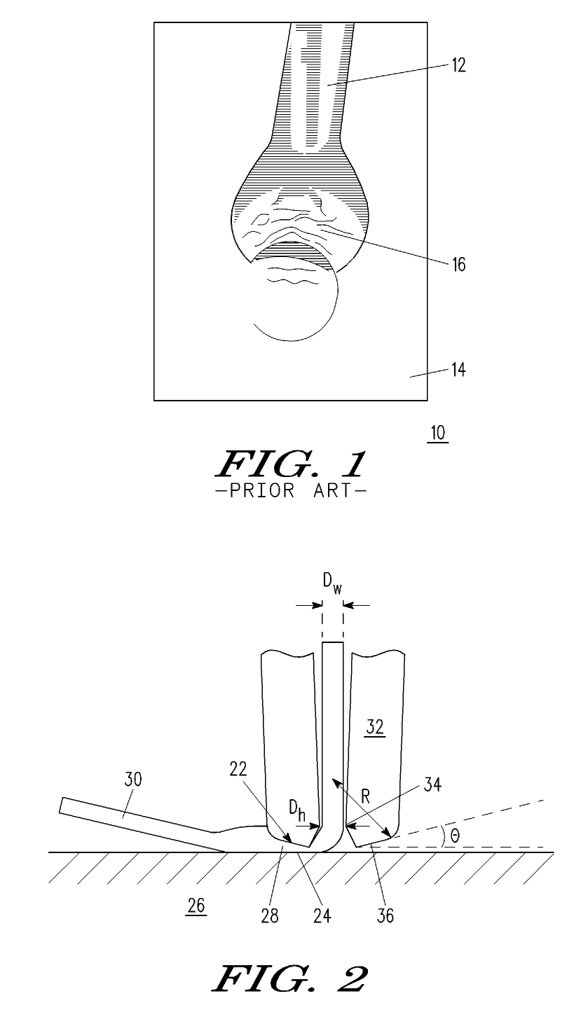

Referring now to FIGS. 2 through 6, a method of forming a forward-folded type stitch bond 20 will now be described. The wirebonding process described below may be performed using currently available wire bonders such as, those available from Kulicke & Soffa of Willow Grove, Pa., USA and ASM International, Materials Park, Ohio, USA.

Referring now to FIG. 2, a first bond 22 is formed at a first location 24 on a bonding site 26 as shown. More particularly, a first stitch bond 22 is formed at the first location 24 on the bonding site 26. The first stitch bond 22 is formed by bonding a first portion 28 of a wire 30 at the first location 24 on the bonding site 26 with a bonding tool 32.

In the embodiment shown, the first stitch bond 22 is formed after a first wire bond (not shown) is formed on a bond pad (not shown) of a semiconductor chip (not shown) with a first end of the wire 30. In the presently preferred embodiment, the first wire bond is a ball bond. Ball bonding is well known by those of skill in the art and therefore detailed descriptions thereof are not necessary for a full understanding of the invention. After forming the first wire bond on the bond pad, the bonding tool 32, which is still holding the wire 30, rises and moves towards the bonding site 26, creating a loop shape. The first portion 28 of the wire 30 is brought into intimate contact with the first location 24 of the bonding site 26 by the bonding tool 32 and the first stitch bond 22 is formed on the bonding site 26 by applying a combination of heat, pressure, and/or ultrasonic energy. Heat may be applied using either a heated bonding tool 32, a heated pedestal (not shown) on which the chip carrier is placed, or both. Such formation of the first stitch bond 22 is well known in the art. Example wire bonder parameters for the formation of the first stitch bond 22 are ultrasonic energy: 12 mA, time: 12 ms, force: 300 g, and bonding temperature: 150° C. The present invention is not limited to a particular set of bonding parameters, as the optimum bonding parameters are dependent on wire type, pad metallization and device configurations.

In one embodiment, the bonding site 26 comprises a lead frame finger. Nonetheless, those of skill in the art will understand that the present invention is not limited to lead frame packaging. In alternative embodiments, the bonding site 26 may be a pad surface of a substrate. Lead frames, substrates and their respective bonding sites are known to those of ordinary skill in the art and therefore, detailed descriptions thereof are not necessary for a full understanding of the invention.

Gold (Au) and aluminium (Al) wire are most commonly used in wirebonding. Both gold and aluminum are strong and ductile and have similar resistance in most environments. Gold wire is sometimes doped with a dopant, such as beryllium (Be) or calcium (Ca) in order to stabilize it. Small-diameter aluminium wire is often doped with silicon (Si) or sometimes magnesium (Mg) to improve its breaking load and elongation parameters. In addition to gold and aluminum, copper (Cu), palladium (Pd) alloy, platinum (Pt) and silver (Ag) bonding wire are also known.

In one embodiment, the wire 30 has a diameter D_{w} of between about 20.3 microns (μm) to about 50.8 μm, although wires of other diameters may also be used and the invention should not be limited to a particular wire diameter. As is known by those of skill in the art, various size wires are available for connecting the semiconductor chip to the chip carrier, with the wire size being selected based on, among other things, the spacing between the bonding sites.

The wire 30 extends though a hole 34 in the bonding tool 32. In the embodiment shown, the bonding tool 32 is a capillary having an outside radius R defined by a curved surface of between about 0.01 millimeters (mm) and about 0.076 mm, an angle θ of between about 6° to about 11° between a bottom face 36 of the capillary and the bonding site 26, which is typically horizontal, and a hole diameter Dₕ of between about 24 μm and about 65 μm. The capillary bonding tool 32 may be made from ceramic, tungsten or ruby materials, as are typically used. Such a bonding tool is well known in the art and therefore, further description of the capillary is not required for a complete understanding of the present invention.

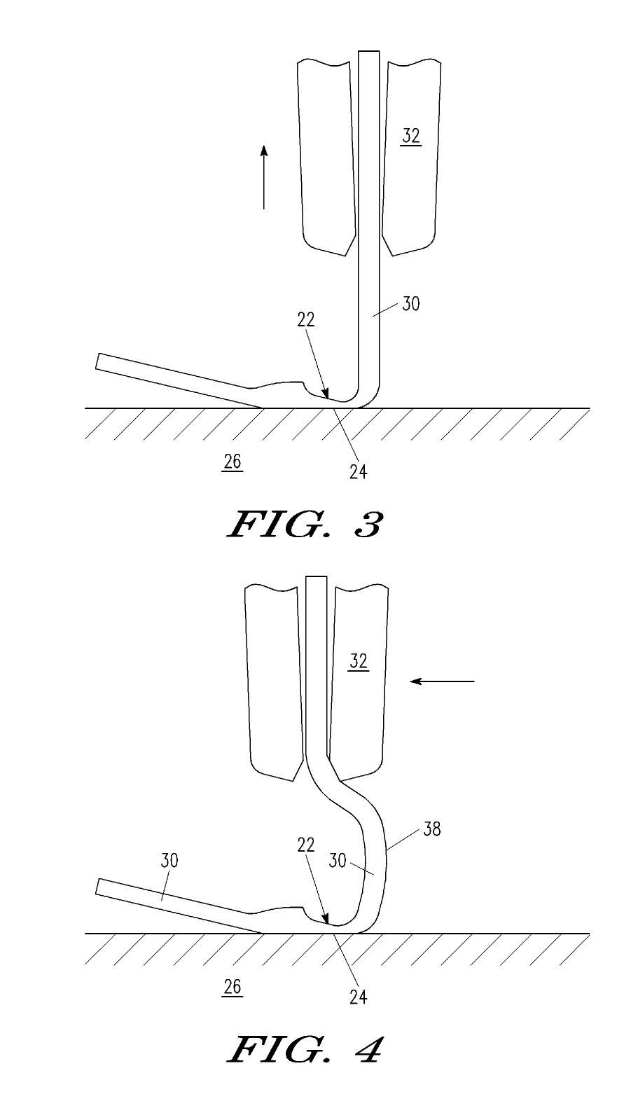

Once the first stitch bond 22 is formed, the bonding tool 32 is raised in an upward movement, as indicated by the arrow in FIG. 3, to pay out a length of the wire 30. In one embodiment, the bonding tool 22 is raised to a height of about two to three times the wire diameter over the bonding site 26.

The bonding tool 32 is then moved back over the first stitch bond 22 and the first location 24 in a reverse movement as indicated by the arrow in FIG. 4. More particularly, the bonding tool 32 is moved in a straight line towards the bond on the semiconductor chip. A fold 38 is formed in the wire 30 when the bonding tool 32 is moved over the first stitch bond 22.

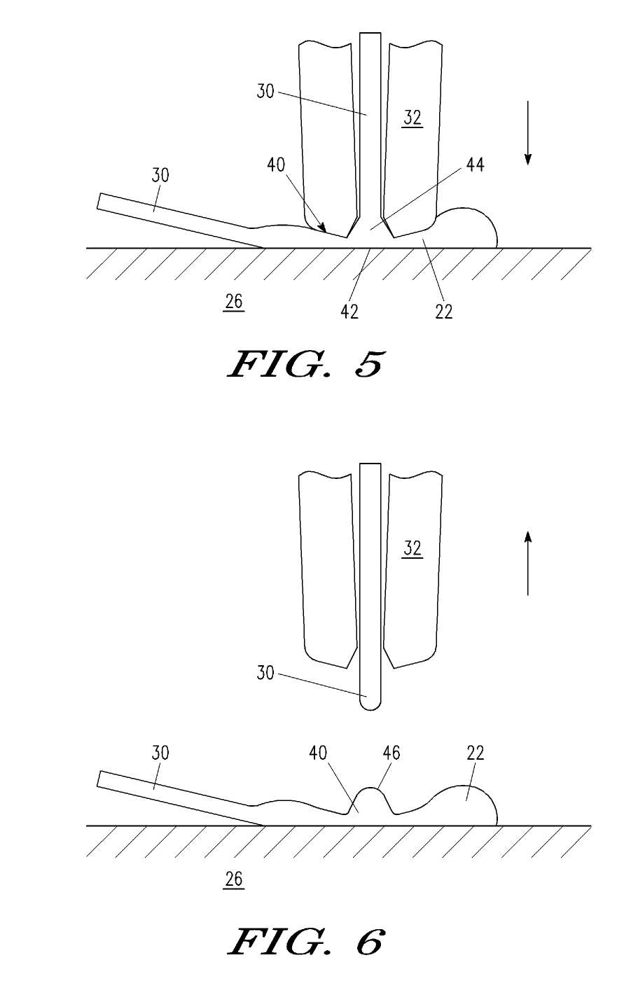

Referring now to FIG. 5, a second bond 40 is formed at a second location 42 on the bonding site 26. The second bond 40 at least partially overlaps the first stitch bond 22. In one embodiment, the second bond 40 is a second stitch bond formed over the first stitch bond 22 at the second location 42 on the bonding site 26. The second stitch bond is formed by lowering the bonding tool 32 over the first stitch bond 22, and bonding a second portion 44 of the wire 30 at the second location 42 on the bonding site 26 with the bonding tool 32. In one embodiment, the second bond 40 partially overlaps the first bond 22 and in another embodiment, the second bond 40 completely overlaps the first bond 22.

The second stitch bond 40 is formed on the bonding site 26 by applying a combination of heat, pressure, and/or ultrasonic energy. In one embodiment, for a QFN (Quad Flat No lead) type package, the second stitch bond 40 is formed using: ultrasonic energy: 12 mA, Time: 12 ms, Force: 300 g, and bonding temperature: 150° C. However, as previously mentioned, those of skill in the art will understand that the present invention is not limited to a particular set of bonding parameters. Rather, the optimum bonding parameters are dependent on wire type, pad metallization and device configurations.

The formation of the second bond 40 over the first stitch bond 22 increases the contact area between the wire bond 20 and the bonding site 26, as well as the thickness of the wire bond 20. The increase in contact area and wire bond thickness enhances the adhesion of the wire bond 20 to the bonding site 26, which in turn improves wire bond performance and reliability.

Referring now to FIG. 6, the wire 30 is broken at a point 46 between the bonding tool 32 and the second bond 40 after the formation of the second bond 40 by raising the bonding tool 32 in the direction of the arrow. Since after the formation of the first bond 22, the bonding tool is raised and then moved back over the bonding site 26, causing a fold in the wire 30, the bond 20 is referred to as a forward-folded bond.

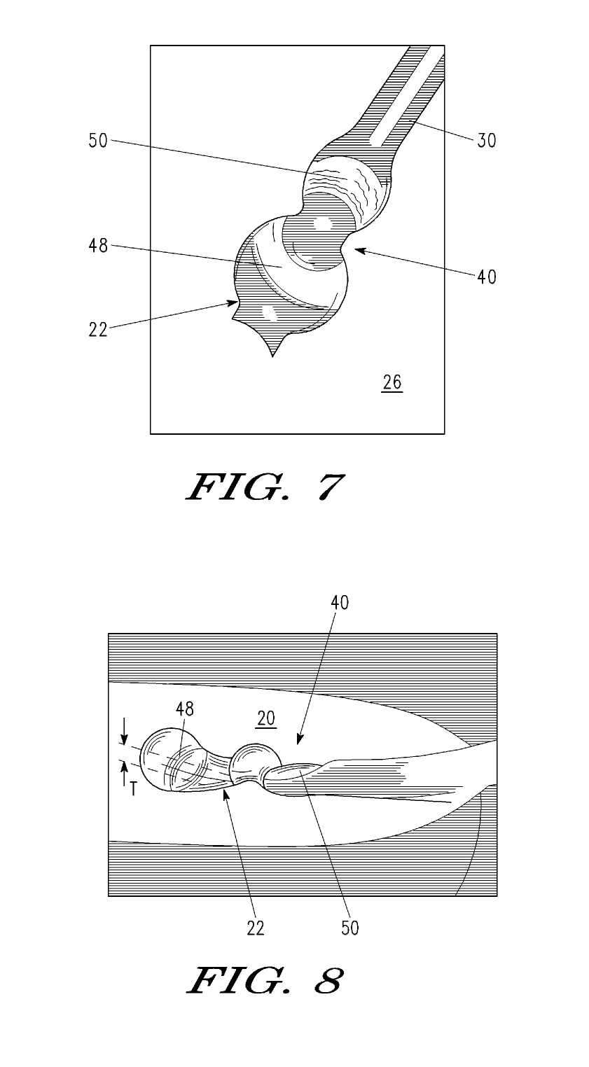

Referring now to FIG. 7, an enlarged top plan view of the forward-folded type stitch bond 20 of FIG. 6 is shown. As can be seen from FIG. 7, the second bond 40 includes first and second crescent-shaped areas 48 and 50. The first and second crescent-shaped areas 48 and 50 of the forward-folded type stitch bond 20 are made by an imprint of an outer geometry of the capillary bonding tool 32.

Referring now to FIG. 8, an enlarged side view of the forward-folded type stitch bond 20 of FIG. 7 is shown. As can be seen from FIG. 8, the first crescent-shaped area 48 overlaps the first stitch bond 22. More particularly, as shown in FIG. 8, the second bond 40 entirely overlaps the first stitch bond 22 such that the second bond 40 substantially entirely covers the first stitch bond 22. Nonetheless, it should be understood that the present invention is not limited by the degree of overlap between the first and second stitch bonds 22 and 40. Rather, the degree of overlap depends on wirebonding process parameters such as, for example, the length of the wire 30 paid out by the bonding tool 32 and/or the reverse distance traveled by the bonding tool 32 prior to the formation of the second stitch bond 40.

The first crescent-shaped area 48 has a thickness T of about two or more times a thickness of the first stitch bond 22. In preferred embodiments, the first crescent-shaped area 48 has a thickness T of at least about 4 um (for 1.0 mil wire for example); a thicker wire would have a thicker crescent-shaped area.

A comparison of the peel strength of the forward-folded type stitch bond and a conventional stitch bond was made by performing a peel strength test on a hundred (100) forward-folded type stitch bonds and repeating the test on a hundred (100) conventional stitch bonds. The results of the comparison are shown in Table 1 below.

| | Forward-Folded | Conventional |
|---|---|---|
| | Type Stitch Bond | Stitch Bond |
| Min. Peel Force | 4.909 g | 2.517 g |
| Max. Peel Force | 8.384 g | 7.459 g |
| Mean Peel Force | 5.822 g | 4.739 g |

As can be seen from Table 1, when taking 1.0 mil wire for example, the mean peel force of the forward-folded type stitch bonds is about 1.1 grams (g) higher than that of the conventional stitch bonds. Thus, it can be said that the forward-folded type stitch bond has increased peel strength. In preferred embodiments, the forward-folded type stitch bond has a peel strength of at least about _{—}4.9 gram (1.0 mil wire for example); thicker wire would have an even greater peel strength improvement.

As is evident from the foregoing discussion, the present invention provides a wire bond with increased peel strength and bond area thickness, and a method of forming such a wire bond. Advantageously, the formation of a second stitch bond over a first stitch bond increases: the contact area between the wire bond and the bonding site, as well as the thickness of the wire bond. The increase in contact area and wire bond thickness enhances the adhesion of the wire bond to the bonding site, which in turn improves wire bond performance and reliability. Apart from increasing peel strength, the increase in wire bond thickness also reduces the risk of heel cracking. Further advantageously, because the present invention can be implemented using currently available wire bonders, there is no need for additional capital investment.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. In a semiconductor package having a plurality of wire bond interconnections between a semiconductor chip and a chip carrier, a wire bond comprising:
a first stitch bond formed at a first location on a bonding site; and
a second stitch bond formed at a second location on the bonding site, the second bond at least partially overlapping the first bond, wherein the second stitch bond includes first and second crescent-shaped areas, the first of which overlaps the first stitch bond.

2. The wire bond of claim 1, wherein the second bond entirely overlaps the first bond.

3. The wire bond of claim 1, wherein the first crescent-shaped area has a thickness of at least about two or more times a thickness of the first stitch bond.

4. The wire bond of claim 3, wherein for a wire having a diameter of about 1.0 mils, the first crescent-shaped area has a thickness of at least about 4 um.

5. The wire bond of claim 1, wherein the bonding site comprises a lead finger of a lead frame.

6. The wire bond of claim 1, wherein the wire has a diameter of about 1.0 mil and the wire bond has a peel strength of at least about 4.9 g.

7. The wire bond of claim 1, wherein the wire bond is formed with a wire having a diameter of between about 0.8 μm to about 2.0 μm.

8. The wire bond of claim 1, wherein the wire is made of one of gold, aluminum, copper, silver, platinum, palladium and an alloy thereof.

9. A semiconductor packaged device, comprising:
a lead frame having a plurality of lead fingers;
a chip attached to the lead frame, the chip having a plurality of bond pads; and
a plurality of wires electrically connecting ones of the bond pads with respective ones of the lead fingers, wherein a bond connecting one of the wires to a corresponding lead finger is a forward-folded type stitch bond.

10. The semiconductor packaged device of claim 9, wherein the forward-folded type stitch bond comprises a first stitch bond formed at a first location on the corresponding lead finger, and a second stitch bond formed at a second location on the corresponding lead finger, wherein the second stitch bond includes first and second crescent-shaped areas, the first crescent-shaped area substantially entirely overlapping the first stitch bond.

11. The semiconductor package of claim 10, wherein the forward-folded type stitch bond has a peel strength of at least about 4.9 g.

12. A method of forming a wire bond, comprising the steps of:
forming a first stitch bond by bonding a first portion of a wire at a first location on a bonding site with a bonding tool; and
forming a second stitch bond by bonding a second portion of the wire at a second location on the bonding site with the bonding tool, wherein the second bond at least partially overlaps the first bond, and wherein the step of forming the second bond comprises,
raising the bonding tool, thereby paying out a length of the wire;
moving the bonding tool back over the first bond and the first location;
lowering the bonding tool over the first bond and forming a second stitch bond over the first bond at the second location; and
raising the bonding tool and breaking the wire at a point between the bonding tool and the second stitch bond.

13. The method of forming a wire bond of claim 12, wherein the second stitch bond substantially entirely covers the first bond.

14. The method of forming a wire bond of claim 13, wherein moving the bonding tool over the first bond forms a fold in the wire.

15. The method of forming a wire bond of claim 12, wherein the bonding site comprises a lead frame finger.
